(19) United States
(12) Patent Application Publication
(10) Pub. No.: US 2025/0349794 A1
(43) Pub. Date: Nov. 13, 2025

(54) PACKAGE ASSEMBLY AND METHOD OF FORMING THE SAME

(71) Applicant: Taiwan Semiconductor Manufacturing Company, Ltd., Hsinchu (TW)

(72) Inventors: Feng-Wei KUO, Hsinchu County (TW); Wen-Shiang Liao, Miaoli County (TW)

(73) Assignee: Taiwan Semiconductor Manufacturing Company, Ltd., Hsinchu (TW)

(21) Appl. No.: 18/658,962

(22) Filed: May 8, 2024

(51) Int. Cl. H01L 25/04; G02B 6/42; H01L 21/48; H01L 23/00

(52) U.S. Cl. CPC H01L 25/042; G02B 6/4214; H01L 21/481; H01L 24/08; H01L 24/80; H01L 2224/08225; H01L 2224/80895; H01L 2224/80896

(57) ABSTRACT

A method of forming a package assembly includes the following operations. An interposer structure, a first die and a second die are provided. The interposer structure includes a first tilted metal layer and a second tilted metal layer facing each other. The first die includes a first substrate and a third tilted metal layer embedded in a first insulating layer on the first substrate. The second die includes a second substrate and a fourth tilted metal layer embedded in a second insulating layer on the second substrate. The first die and the second die are bonded to the interposer structure with the first substrate and the second substrate facing up, so that a light beam from an optical fiber over the first die is reflected by the third tilted metal layer, the first tilted metal layer, the second tilted metal layer, and the fourth tilted metal layer sequentially.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area. Although the existing integrated circuit packages or package assemblies have been generally adequate for their intended purposes, they have not been entirely satisfactory in all respects.

### BRIEF DESCRIPTION OF THE DRA WINGS

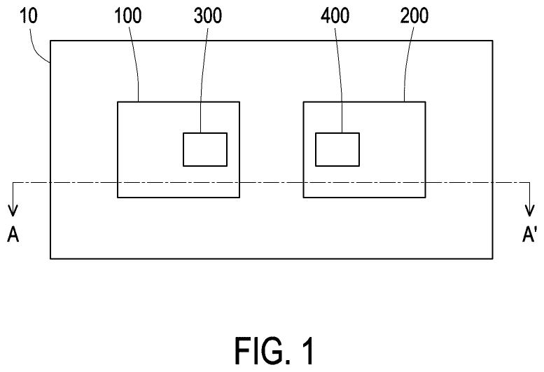

FIG. 1 is a simplified top view of a package assembly in accordance with some embodiments.

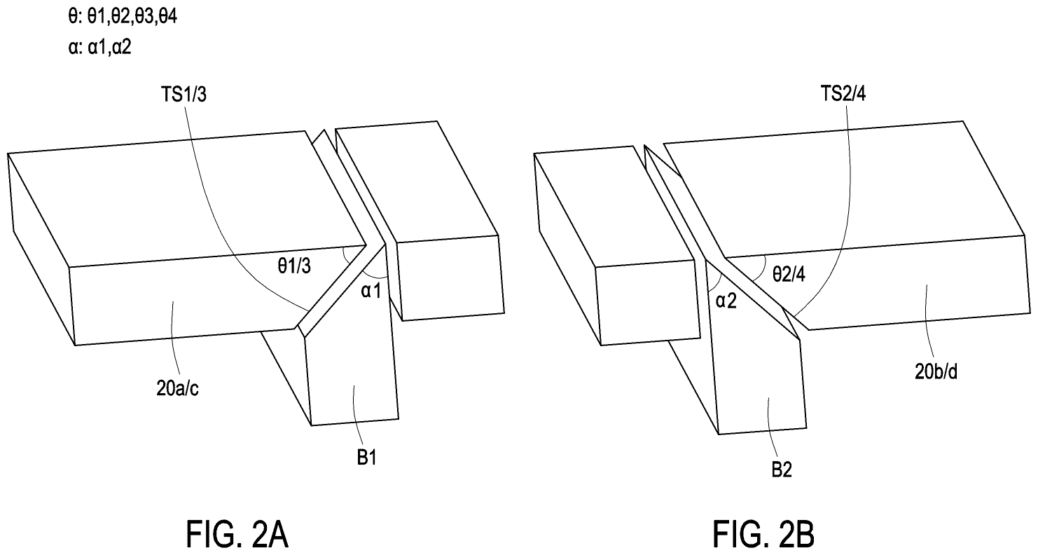

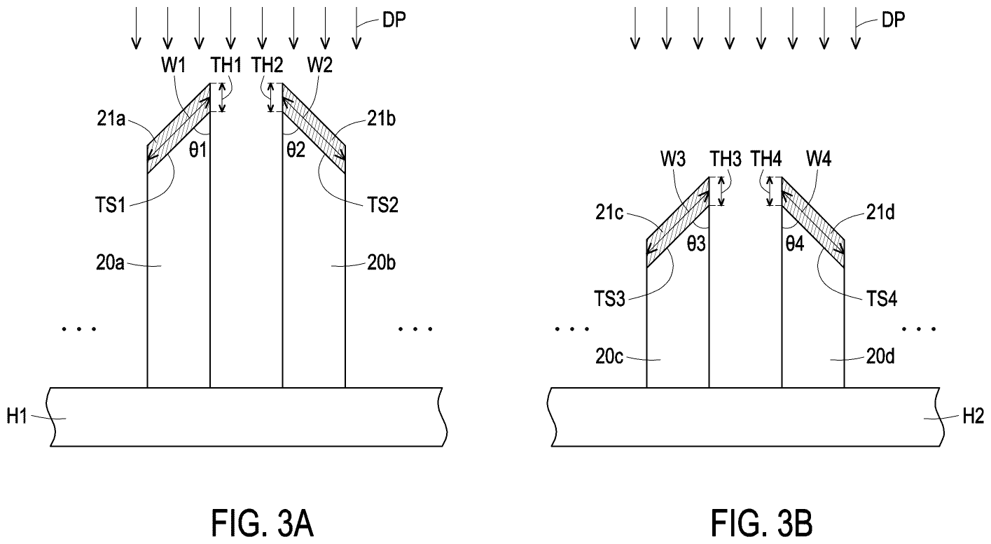

FIG. 2A, FIG. 2B, FIG. 3A and FIG. 3B are different views of a method of forming glass substrates with mirrors in accordance with some embodiments.

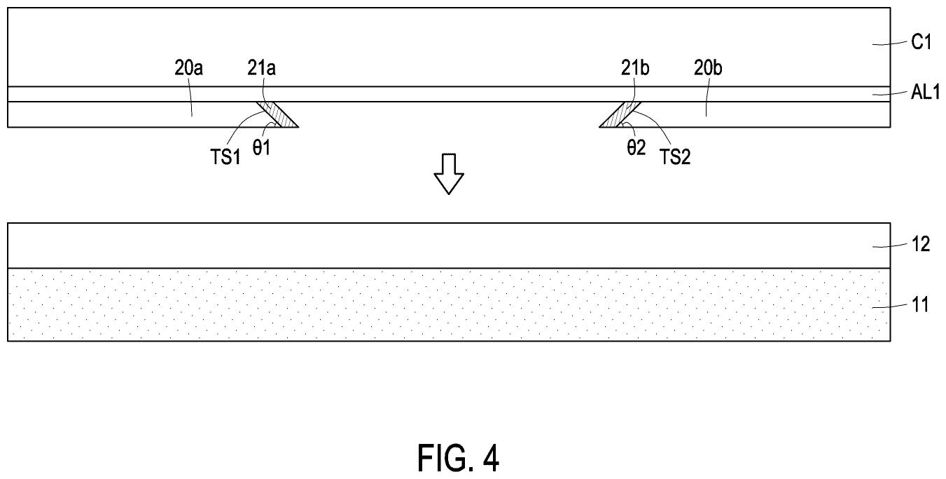

FIG. 4 to FIG. 11 are schematic cross-sectional views of a package assembly in accordance with some embodiments.

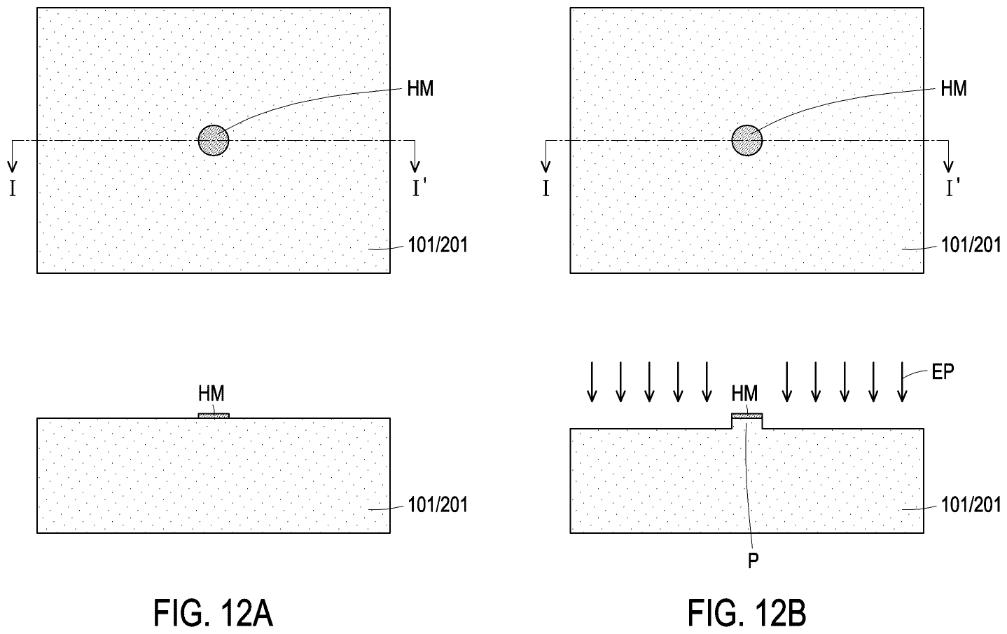

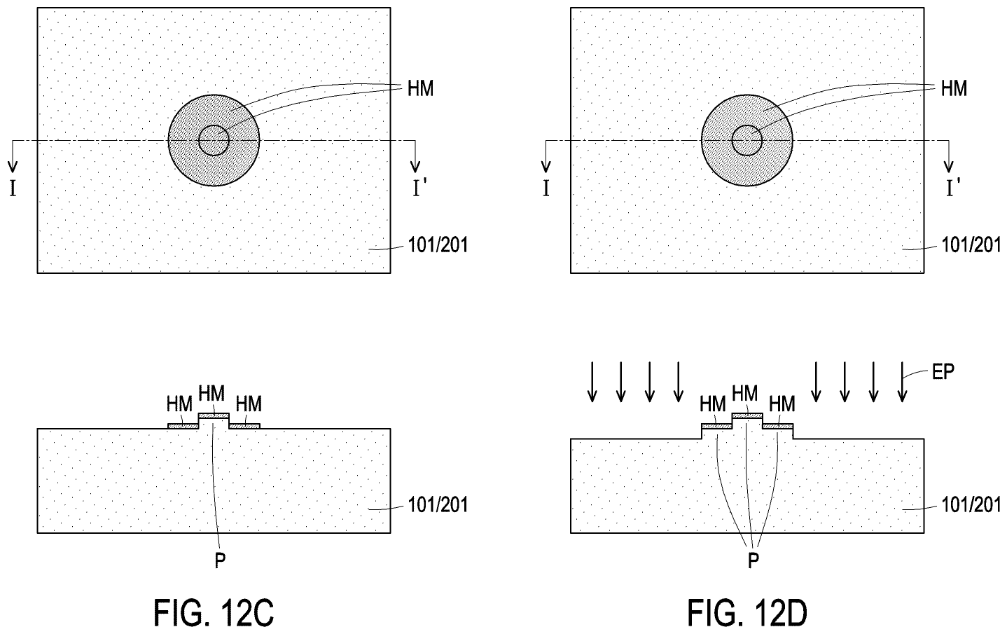

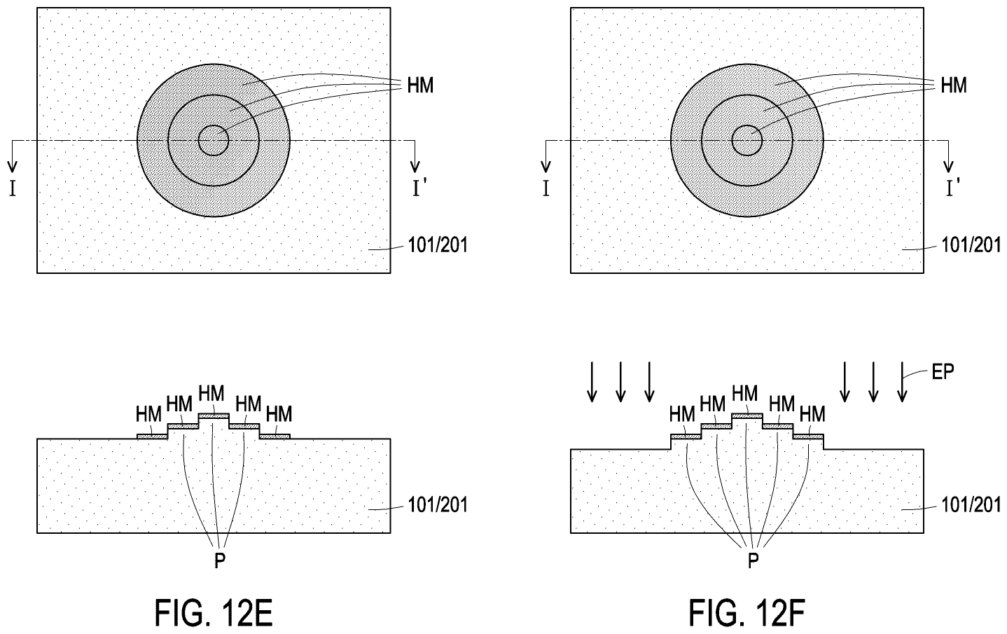

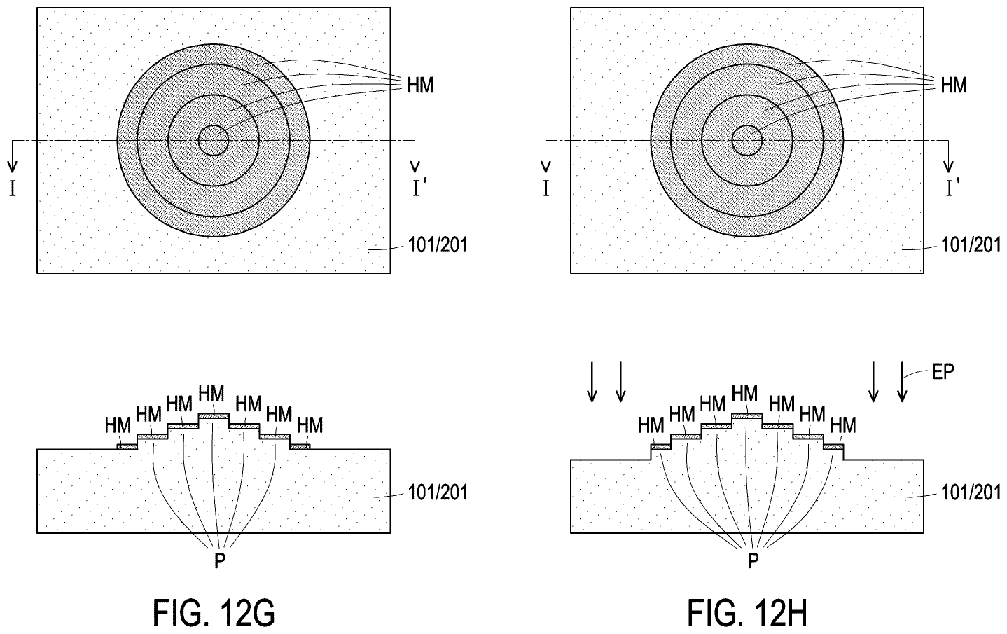

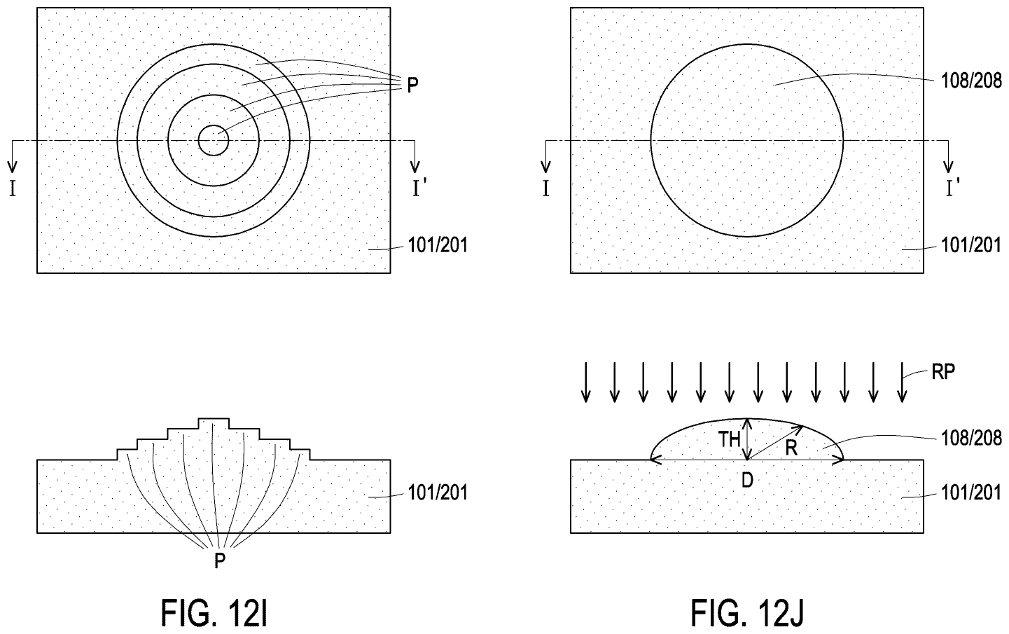

FIG. 12A to FIG. 12J are local top views and cross-sectional views of a method of forming an optical lens in accordance with some embodiments.

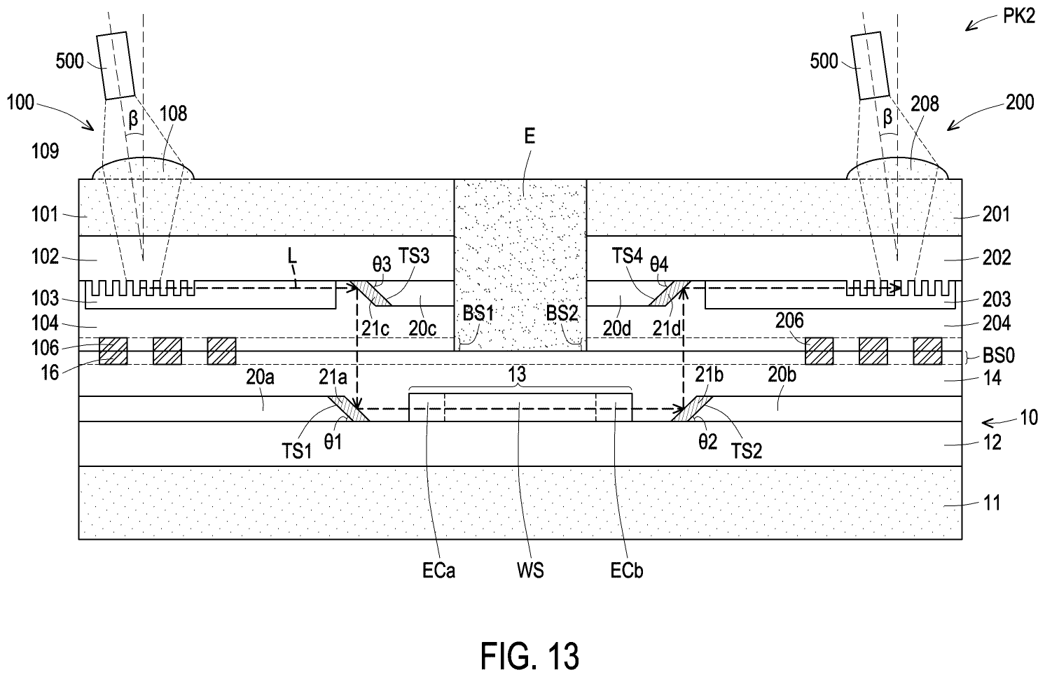

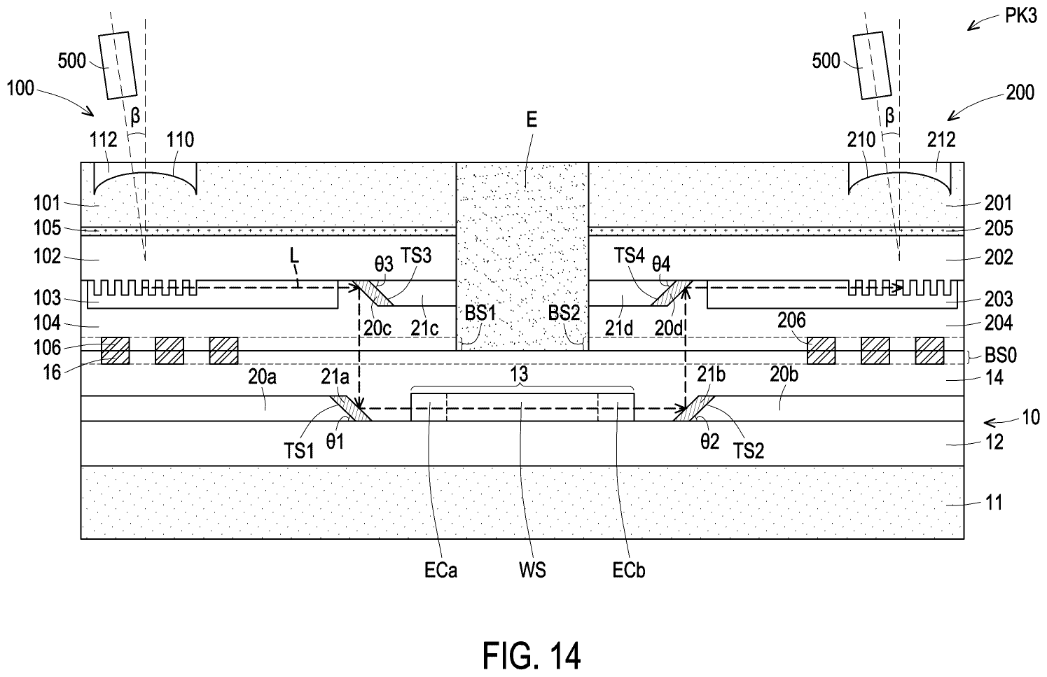

FIG. 13 to FIG. 14 are schematic cross-sectional views of package assemblies in accordance with some embodiments.

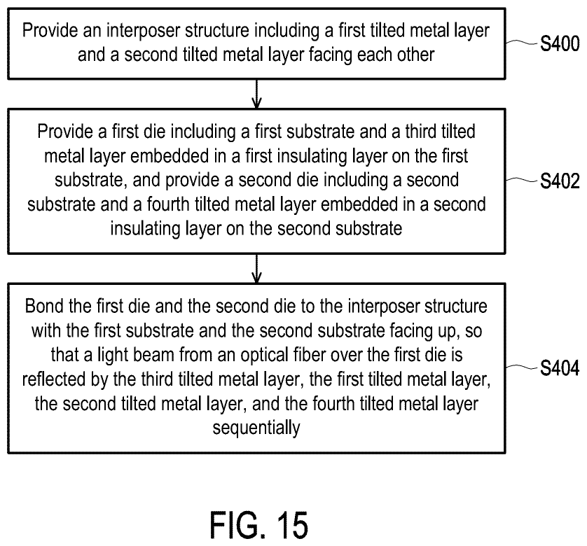

FIG. 15 illustrates a method of forming a package assembly in accordance with some embodiments.

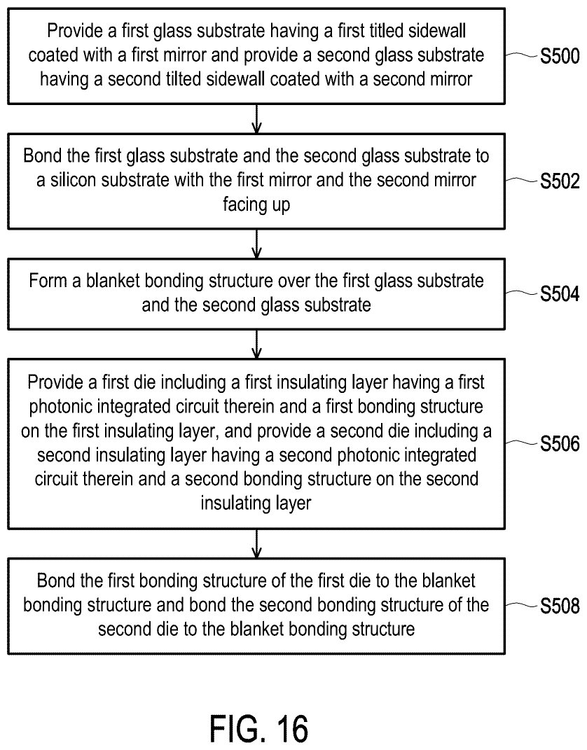

FIG. 16 illustrates a method of forming a package assembly in accordance with some embodiments.

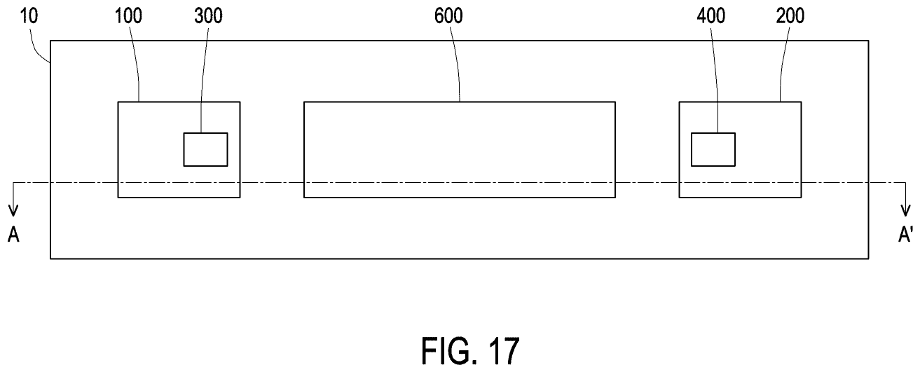

FIG. 17 is a simplified top view of a package assembly in accordance with some embodiments.

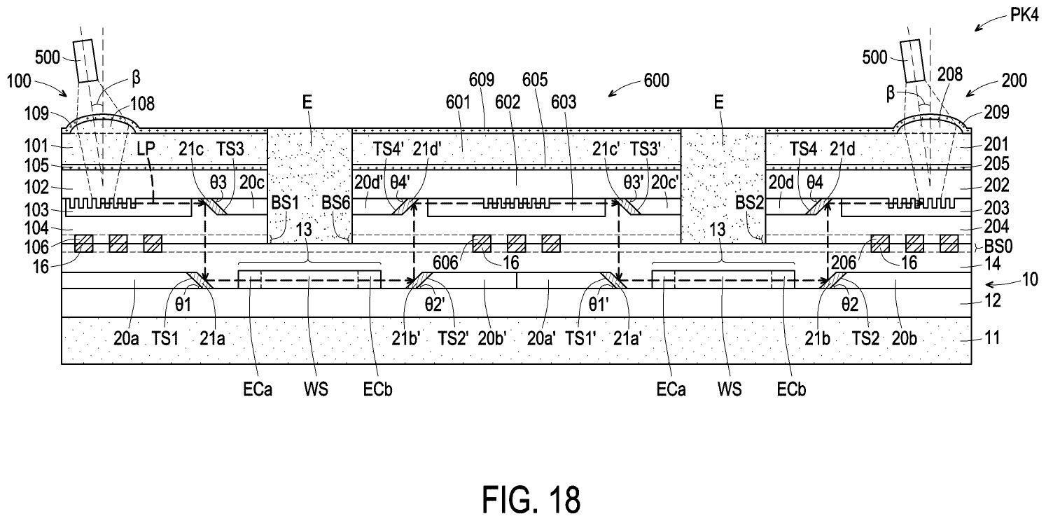

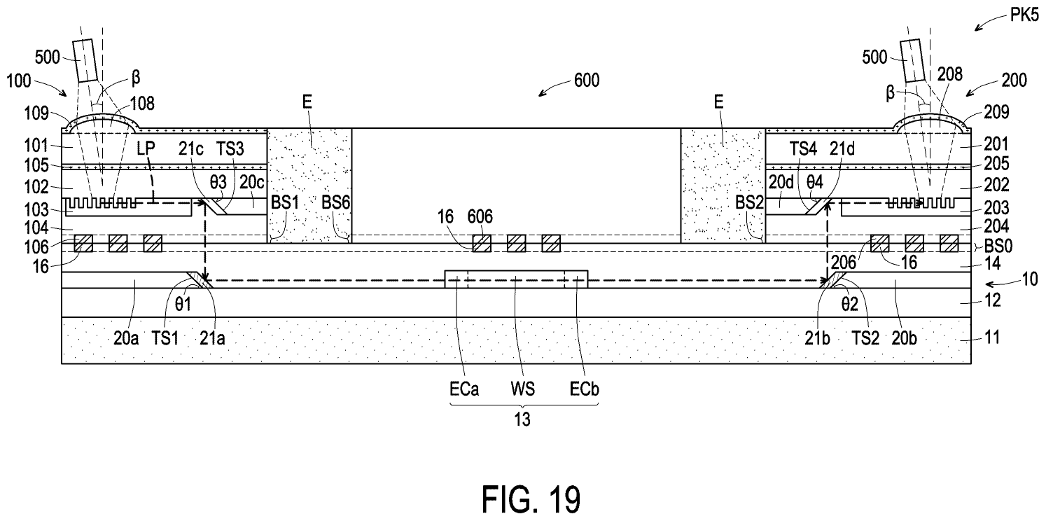

FIG. 18 to FIG. 19 are schematic cross-sectional views of package assembles in accordance with some embodiments.

### DETAILED DESCRIPTION

The following disclosure provides many different embodiments, or examples, for implementing different features of the provided subject matter. Specific examples of components and arrangements are described below for the purposes of conveying the disclosure in a simplified manner. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the same or similar reference numerals and/or letters may be used to refer to the same or similar element in the various examples of the disclosure. The repeated use of the reference numerals is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein to facilitate the description of one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments described herein disclose package assemblies such as photonic-electronic integrated circuit (IC) packages. First, mirrors are fabricated on thinned glass substrates in a mass production, so as to significantly reduce the cycle time of a package assembly. The appropriate number of the glass substrates with the mirrors is embedded in suitable positions of an interposer structure and at least two photonic dies, so that the interposer structure is optically coupled to the at least two photonic dies, and therefore the coupling efficiency is greatly improved. With optical interconnection provided by the interposer structure and the photonic dies, higher communication performance and more compact packaging can be easily achieved.

FIG. 1 is a simplified top view of a package assembly in accordance with some embodiments. For clarity and illustration purposes, only dies and interposer structure are shown in FIG. 1. The package assembly may be a photonic-electronic integrated circuit (IC) package including at least one photonic die and at least one electronic die integrated with each other. In some embodiments, FIG. 4 to FIG. 11 are schematic cross-sectional views of a package assembly taken along the line A-A of FIG. 1.

Referring to FIG. 1, dies 100 and 200 are disposed side by side on an interposer structure

10. The dies 100 and 200 may be photonic dies. Each of the photonic dies 100 and 200 includes a photonic integrated circuit (PIC) or an integrated optical circuit. For examples, each of the photonic dies 100 and 200 includes optical components such as an optical waveguide, a modulator, a detector, an edge coupler, a grating coupler, a mirror, a filter, other optical components, or a combination thereof.

Dies 300 and 400 are located aside the dies 100 and 200. In some embodiments, the dies 300 and 400 may be electronic dies. Each of the electronic dies 300 and 400 includes an electronic integrated circuit (EIC). For examples, each of the electronic dies 300 and 400 includes electronic components such as an active component, a passive component or a combination thereof. In some embodiments, the dies 300 and 400 are stacked on the dies 100 and 200, respectively. In some embodiments, the dies 300 and 400 are embedded in insulating layers of the dies 100 and 200, respectively.

The photonic integrated circuit (PIC) of the photonic die is integrated with the electronic integrated circuit (EIC) of the electronic die. The PIC can generate an optical signal based on an input from an EIC, typically in the visible spectrum or near infrared 850 nm-1650 nm. The electronic die may be a silicon-based die. Unlike electronic integration where silicon is the dominant material, the photonic integrated circuits have been fabricated from a variety of materials, including electro-optic crystals such as lithium niobate, silica on silicon, silicon on insulator, various polymers and semiconductor materials such as GaAs and InP.

In some embodiments, the interposer structure 10 of the disclosure may be not only optically coupled to the photonic dies 100 and 200 but also electrically coupled to the electronic dies 300 and 400. In some embodiments, the interposer structure 10 includes a photonic integrated circuit (PIC) optically coupled to the overlying photonic dies 100 and 200. For examples, the interposer structure 10 includes optical components such as an optical waveguide, a modulator, an edge coupler, a detector, a grating coupler, a mirror, a filter, other optical components, or a combination thereof. In some embodiments, the interposer structure 10 further includes wiring patterns electrically coupled to the overlying electronic dies 300 and 400.

In the disclosure, mirrors are prepared on glass substrates in a mass production, so as to significantly reduce the cycle time of a package assembly. The method of forming glass substrates with mirrors are described below.

FIG. 2A, FIG. 2B, FIG. 3A and FIG. 3B are different views of a method of forming glass substrates with mirrors in accordance with some embodiments.

Referring to FIG. 2A and FIG. 2B, multiple blanket glass substrates 20a, 20b, 20c and 20d are provided. The blanket glass substrates 20a, 20b, 20c and 20d may be bulk glass substrates without tilted sidewalls. The blanket glass substrates have a thickness of about 300 μm or more (e.g., about 300-750 μm). The blanket glass substrates include SiO₂. In some embodiments, a SiO₂ glass substrate is composed of SiO₄ tetrahedral units connected together by oxygen atoms forming rings of different sizes, from 3 up to 10 units.

Thereafter, the blanket glass substrates are beveled, so that each beveled glass substrate has a tilted sidewall. The included angle θ between the tilted sidewall and the adjacent top surface of the beveled glass substrate ranges from about 1 degree to about 89 degrees or from about 30 degrees to about 80 degrees (e.g., about 45 degrees), depending on the blade angle α of the dicing blade. In some embodiments, the sum of the included angle θ of the beveled glass substrate and the blade angle α of the dicing blade is about 90 degrees, as shown in FIG. 2A and FIG. 2B.

In some embodiments, the blanket glass substrates 20a and 20c are beveled by a dicing blade B1, so that the beveled glass substrate 20a and 20c have tilted sidewalls TS1 and TS3, respectively. In some embodiments, the included angle θ1 between the tilted sidewall TS1 and the adjacent top surface of the beveled glass substrate 20a is about 1 degree to about 89 degrees (e.g., about 45 degrees), and the included angle θ1 between the tilted sidewall TS3 and the adjacent top surface of the beveled glass substrate 20c is about 1 degree to about 89 degrees (e.g., about 45 degrees).

In some embodiments, the blanket glass substrates 20b and 20d are beveled by a dicing blade B2, so that the beveled glass substrate 20b and 20d have tilted sidewalls TS2 and TS4, respectively. In some embodiments, the included angle θ2 between the tilted sidewall TS2 and the adjacent top surface of the beveled glass substrate 20b is about 1 degree to about 89 degrees (e.g., about 45 degrees), and the included angle θ4 between the tilted sidewall TS4 and the adjacent top surface of the beveled glass substrate 20d is about 1 degree to about 89 degrees (e.g., about 45 degrees).

Referring to FIG. 3A and FIG. 3B, the beveled glass substrates stand on a temporary holder with tilted sidewalls facing up. The beveled glass substrates may be grouped by their heights and placed on different temporary holders through adhesive layers, respectively. In some embodiments, the beveled glass substrates 20a and 20b stand on a temporary holder H1 with tilted sidewalls TS1 and TS2 facing up. In some embodiments, the beveled glass substrates 20c and 20d stand on a temporary holder H2 with tilted sidewalls TS3 and TS4 facing up.

Thereafter, a metal material is deposited on the tilted sidewalls by a deposition process DP. Specifically, mirrors 21a, 21b, 21c and 21d are formed on the tilted sidewalls TS1, TS2, TS3 and TS4 of the glass substrates 20a, 20b, 20c and 20d, respectively. The mirrors are referred to as “tilted metal layers” or “45 degrees reflectors” in some examples. In some embodiments, the metal material includes Cu, Al, Co, Cr, W, Ti, Ta, the like or a combination thereof. The deposition process DP includes a sputtering process, a physical vapor deposition (PVD) process, an evaporating process, a vapor phase deposition (VPD) process, or the like.

Afterwards, the temporary holder H1 is removed from the beveled glass substrates 20a and 20b, and the temporary holder H2 is removed from the glass substrates 20c and 20d. The glass substrates 20a, 20b, 20c and 20d with mirrors 21a, 21b, 21c and 21d are thus completed. The mirrors 21a, 21b, 21c and 21d may have substantially uniform thickness TH1, TH2, TH3 and TH4. Each of the thickness TH1, TH2, TH3 and TH4 ranges from about 1 μm to 100 μm (e.g., about 20 μm). The mirrors 21a, 21b, 21c and 21d may have widths W1, W2, W3 and W4. Each of the widths W1, W2, W3 and W4 ranges from about 1 μm to 100 μm (e.g., about 20 μm).

FIG. 4 to FIG. 11 are schematic cross-sectional views of a method of forming a package assembly in accordance with some embodiments. It is understood that the disclosure is not limited by the method described below. Additional operations can be provided before, during, and/or after the method and some of the operations described below can be replaced or eliminated, for additional embodiments of the methods. Although FIG. 4 to FIG. 11 are described in relation to a method, it is appreciated that the structures disclosed in FIG. 4 to FIG. 11 are not limited to such a method, but instead may stand alone as structures independent of the method.

Referring to FIG. 4, a glass substrate 20a having a titled sidewall TS1 coated with a mirror 21a and a glass substrate 20b having a tilted sidewall TS2 coated with a mirror 21b are provided on a carrier C1. In some embodiments, the glass substrate 20a and the glass substrate 20b are manufactured from the process steps described in FIG. 2A, FIG. 2B, FIG. 3A and FIG. 3B. The glass substrate 20a and the glass substrate 20b are picked and placed on the carrier C1 with an adhesive layer AL1 therebetween. The carrier C1 includes a glass carrier or a ceramic carrier. The adhesive layer AL1 includes polydimethylsiloxane (PDMS), or the like. The glass substrate 20a and the glass substrate 20b are picked and placed on the carrier C1 with the mirrors 21a and 21b facing down towards the adhesive layer AL1.

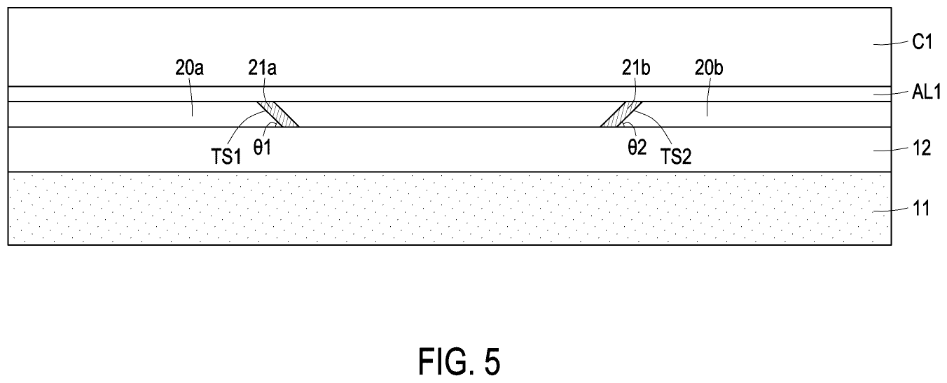

Referring to FIG. 4 and FIG. 5 together, the carrier C1 having the glass substrate 20a and the glass substrate 20b is bonded to a substrate 11, so that the mirror 21a and the mirror 21b are interposed between the carrier C1 and the substrate 11. The substrate 11 includes a silicon substrate. In some embodiments, an insulating layer 12 is formed on the substrate 11, and the carrier C1 having the glass substrate 20a and the glass substrate 20b is attached to the insulating layer 12 on the substrate 11 through a mechanical force. The insulating layer 12 includes SiO₂, SOG, BPSG, TEOS, USG, doped oxide or the like, and the forming method thereof includes performing a deposition process (e.g., CVD, APCVD, SACVD, LPCVD or the like). In some embodiments, the insulating layer 12 has a thickness of about 8 μm or more (e.g., about 10-100 μm). When the carrier C1 is bonded to the substrate 11 with the glass substrates 20a and 20b therebetween, an annealing is performed at a temperature of about 200° C. to 300° C. for about 5 minutes to 20 minutes. Such bonding process is referred to as a “fusion bonding process” or a “low-temperature bonding process” in which the insulating layer 11 is bonded and connected to the glass substrates 20a and 20b.

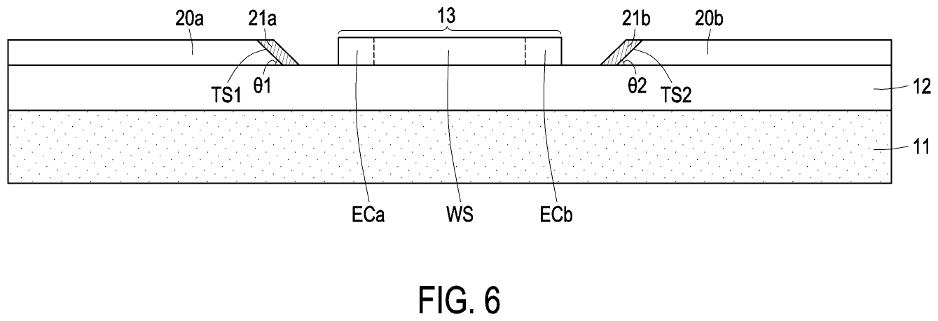

Referring to FIG. 6, the carrier C1 and the adhesive layer AL1 are removed from the glass substrates 20a and 20b by a mechanical peel debonding process or a laser debonding process. After the debonding process, another annealing is optionally performed at a temperature about 200° C. to 300° C. for about 1 hour to 3 hours. Thus, the glass substrates 20a and 20b are bonded to the insulating layer 12 with the mirrors 21a and 21b facing up and facing each other.

Thereafter, a photonic integrated circuit (PIC) 13 is formed between the mirror 21a and the mirror 21b. The mirror 21a and the mirror 21b are configured to reflect a light beam to the desired direction or the desired optical component. The photonic integrated circuit 13 is configured to regulate a light beam from the mirror 21a or the mirror 21b. The photonic integrated circuit 13 includes one or more optical components, such as an optical waveguide, a modulator, a detector, an edge coupler, a grating coupler, a filter, other optical components, or a combination thereof. In some embodiments, the photonic integrated circuit 13 includes an edge coupler ECa, an edge coupler ECb and a waveguide structure WS between the edge coupler ECa and the second coupler ECb, the edge coupler ECa is laterally aligned with the mirror 21a, and the edge coupler ECb is laterally aligned with the mirror 21b. The waveguide structure WS includes a silicon waveguide structure or a silicon nitride waveguide structure. The thickness of the silicon waveguide structure ranges from about 100 nm to 1000 nm or is about 200 nm or more. The thickness of the silicon nitride waveguide structure ranges from about 100 nm to 1000 nm or is about 300 nm. In some embodiments, the method of forming the photonic integrated circuit 13 includes performing film deposition, photoresist patterning, plasma etching (e.g., RIE), photoresist removing and cleaning.

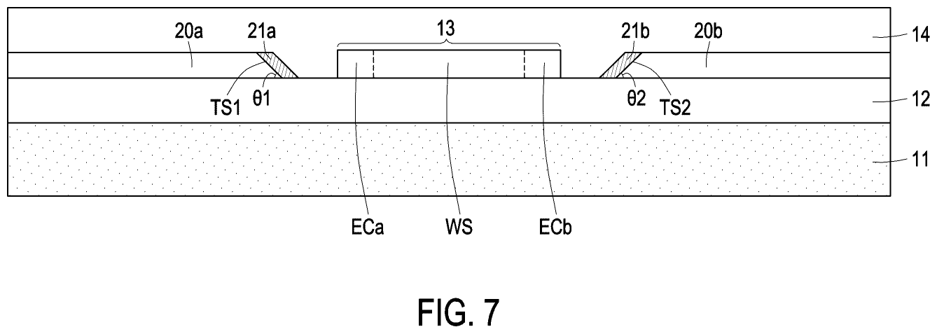

Referring to FIG. 7, an insulating layer 14 is formed over the substrate 11 and covers the glass substrate 20a, the photonic integrated circuit 13 and the glass substrate 20b. The insulating layer 14 includes SiO₂, SOG, BPSG, TEOS, USG, doped oxide or the like. The insulating layer 14 and the insulating layer 12 include the same material or different materials. The method of forming the insulating layer 14 includes performing a deposition process (e.g., CVD, APCVD, SACVD, LPCVD or the like) followed by a planarization process (e.g., CMP). The insulating layer 14 has a planar top surface after the planarization process. In some embodiments, the insulating layer 14 has a thickness of about 8 μm or more (e.g., about 10-100 μm).

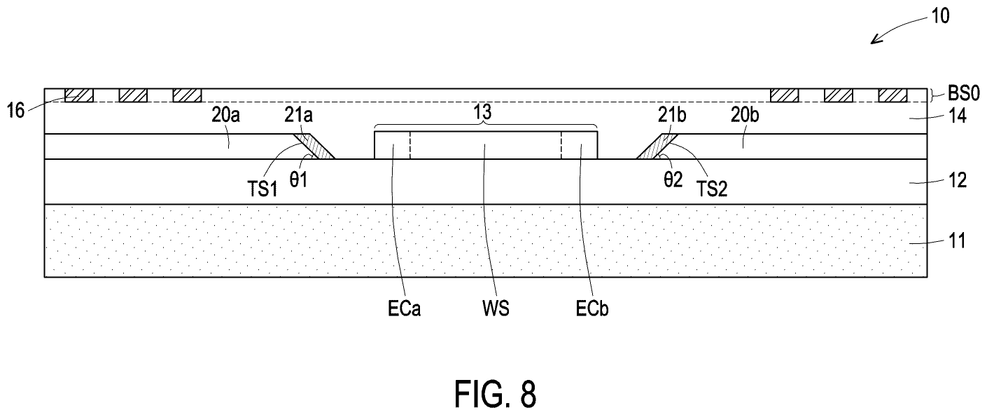

Referring to FIG. 8, bonding metal features 16 are formed in the insulating layer 14. In some embodiments, the bonding metal features 16 includes Cu, Al, Ti, Ta, W, Ru, Co, Ni, the like, or a combination thereof, and the forming method thereof includes performing a damascene process. In some embodiments, a metal liner layer may be disposed between each bonding metal feature and the insulating layer 14. The metal liner layer includes a seed layer and/or a barrier layer. The seed layer may include Ti/Cu. The barrier layer may include Ta, TaN, Ti, TIN, CoW or a combination thereof. The interposer structure 10 of the disclosure is thus completed. In some embodiments, the upper portion of the insulating layer 14 and the bonding metal features 16 form a blanket bonding structure BS0 for the interposer structure 10.

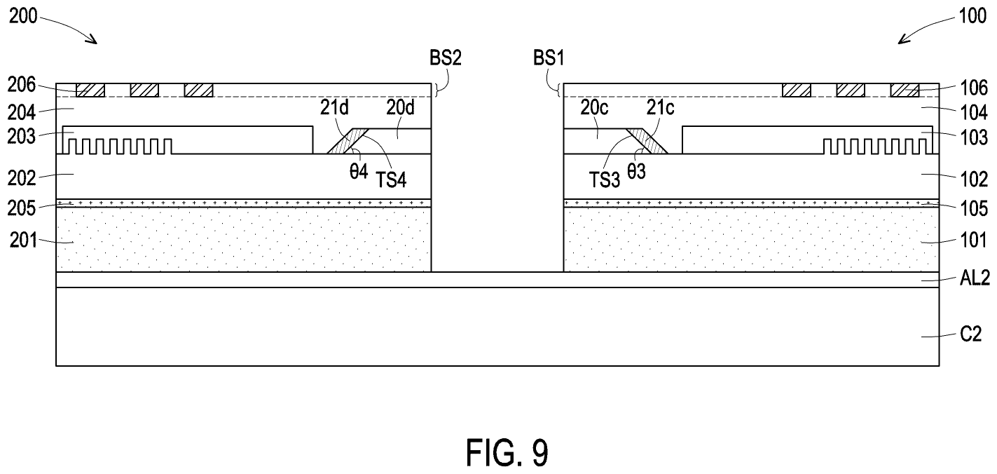

Referring to FIG. 9, a die 100 and a die 200 are provided on a carrier C2 through an adhesive layer AL2. The carrier C2 includes a glass carrier or a ceramic carrier. The adhesive layer AL2 includes a light-to-heat-conversion (LTHC) film, or the like.

In some embodiments, the die 100 includes a substrate 101, an insulating layer 102, a glass substrate 20c, a photonic integrated circuit 103, an insulating layer 104, and bonding metal features 106.

The substrate 101 includes a silicon substrate. In some embodiments, the insulating layer 102 is disposed on the substrate 101. The insulating layer 102 includes SiO₂, SOG, BPSG, TEOS, USG, doped oxide or the like, and the forming method thereof includes performing a deposition process (e.g., CVD, APCVD, SACVD, LPCVD or the like). In some embodiments, an anti-reflective coating (ARC) 105 is optionally formed between the substrate 101 and the insulating layer 102. The anti-reflective coating (ARC) 105 is configured to improve the optical coupling performance. In some embodiments, the anti-reflective coating (ARC) 105 has a multi-layer structure including at least two silicon nitride layers and at least two silicon oxide layers alternatively stacked. Each of the silicon nitride layers and the silicon oxide layers of the anti-reflective coating (ARC) 105 ranges from about 0.1 μm to 5 μm (e.g., about 0.6 μm).

In some embodiments, the glass substrate 20c is disposed on the insulating layer 102. The glass substrate 20c has an inclined sidewall TS3 coated with a mirror 103c. The mirror 21c is configured to reflect a light beam to the desired direction or the desired optical component. In some embodiments, the glass substrate 20c is manufactured from the process steps described in FIG. 2A, FIG. 2B, FIG. 3A and FIG. 3B. The glass substrate 20c is picked and placed on the insulating layer 21c, and then fusion bonded to the insulating layer 102.

In some embodiments, the photonic integrated circuit 103 is laterally disposed on the insulating layer 102 adjacent to the glass substrate 20c. The photonic integrated circuit 103 is configured to regulate a light beam from the mirror 21c. The photonic integrated circuit 103 includes one or more optical components, such as an optical waveguide, a modulator, a detector, an edge coupler, a grating coupler, a filter, other optical components, or a combination thereof. In some embodiments, the photonic integrated circuit 103 includes a grating coupler and a waveguide structure. In some embodiments, the grating coupler is disposed between the waveguide structure and the mirror. The waveguide structure includes a silicon waveguide structure or a silicon nitride waveguide structure. In some embodiments, the method of forming the photonic integrated circuit includes performing film deposition, photoresist patterning, plasma etching (e.g., RIE), photoresist removing and cleaning.

In some embodiments, an insulating layer 104 is formed over the substrate 101 and covers the glass substrate 20c and the photonic integrated circuit 103. The insulating layer 104 includes SiO₂, SOG, BPSG, TEOS, USG, doped oxide or the like. The insulating layer 104 and the insulating layer 102 include the same material or different materials. The method of forming the insulating layer 104 includes performing a deposition process (e.g., CVD, APCVD, SACVD, LPCVD or the like) followed by a planarization process (e.g., CMP). The insulating layer 104 has a planar top surface after the planarization process.

In some embodiments, bonding metal features 106 are formed in the insulating layer 104. In some embodiments, the bonding metal features 106 includes Cu, Al, Ti, Ta, W, Ru, Co, Ni, the like, or a combination thereof, and the forming method thereof includes performing a damascene process. In some embodiments, a metal liner layer may be disposed between each bonding metal feature 106 and the insulating layer 104. The metal liner layer includes a seed layer and/or a barrier layer. The seed layer may include Ti/Cu. The barrier layer may include Ta, TaN, Ti, TiN, CoW or a combination thereof. The die 100 of the disclosure is thus completed. In some embodiments, the upper portion of the insulating layer 104 and the bonding metal features 106 form a bonding structure BS1 for the die 100. In some embodiments, the substrate 101 is regarded as part of the photonic die 100. However, the disclosure is not limited thereto. In other embodiments, an electronic die 300 (see FIG. 1) may be stacked on the photonic die 100 and embedded by an insulating material or a molding compound, and the substrate 101 is regarded as a heat dissipation substrate or a support substrate for the photonic-electronic structure.

The die 200 may have an element configuration similar to that of the die 100. In some embodiments, the element configuration of die 200 is symmetrical to the element configuration of die 200 with respect to a central axis between the die 100 and the die 200.

In some embodiments, the die 200 includes a substrate 201, an insulating layer 202, a glass substrate 20d. a photonic integrated circuit 203, an insulating layer 204, and bonding metal features 206. In some embodiments, the die 200 further includes an anti-reflective coatings (ARC) 205 for improving the optical coupling performance. In some embodiments, the substrate 201, the insulating layer 202, the glass substrate 20d, the photonic integrated circuit 203 the insulating layer 204, the anti-reflective coatings (ARC) 205, and the bonding metal features 206 are similar to those of the substrate 101, the insulating layer 102, the glass substrate 20c, the photonic integrated circuit 103, the insulating layer 104, the anti-reflective coatings (ARC) 105, and the bonding metal features 106, so the materials and the forming methods are not disclosed herein. In some embodiments, the upper portion of the insulating layer 204 and the bonding metal features 206 form a bonding structure BS2 for the die 100.

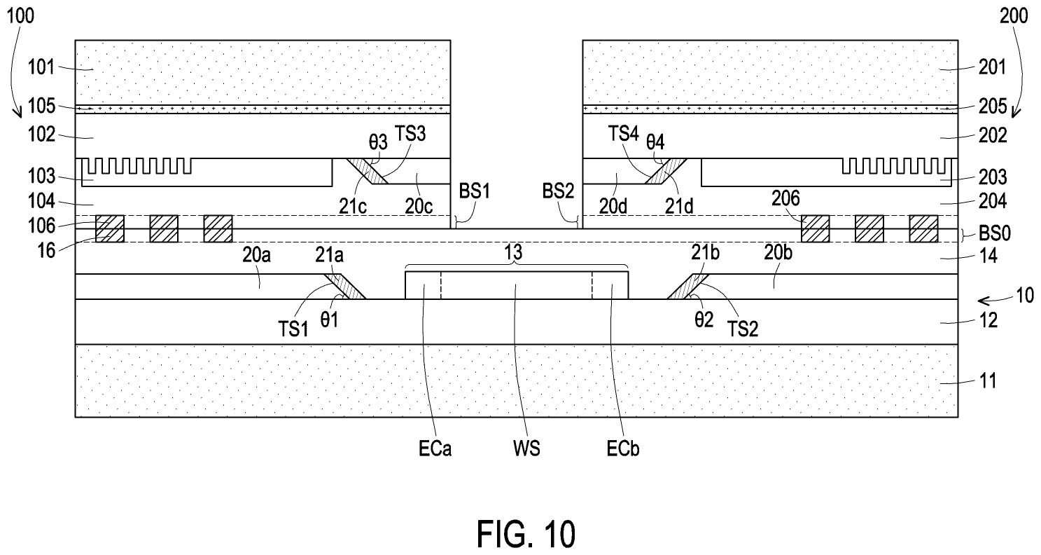

Referring to FIG. 10, the carrier C2 having the dies 100 and 200 is turned over and bonded to the interposer structure 10. Specifically, the bonding structure BSI of the die 100 is bonded to the blanket bonding structure BS0 of the interposer structure 10, and the bonding structure BS2 of the die 200 is bonded to the blanket bonding structure BS0 of the interposer structure 10. Such bonding process is referred to as a “hybrid bonding process” including a metal-to-metal bonding and a dielectric-to-dielectric bonding, in which the bonding metal features 106 and 206 are bonded to the bonding metal features 16, and the insulating layers 104 and 204 are bonded to the insulating layer 14.

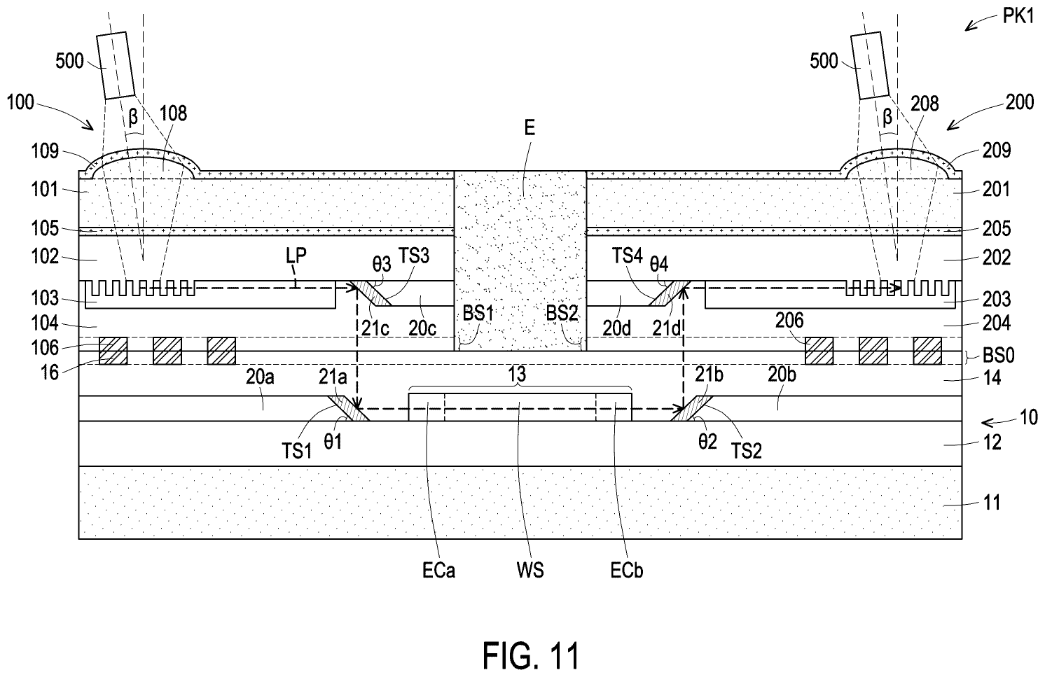

Referring to FIG. 11, an optical lens 108 is formed on the die 100 and an optical lens 208 is formed on the die 200. In some embodiments, the optical lens 108 is formed on the substrate 101 of the die 100 and the optical lens 208 is formed on the substrate 201 of the die 200. The optical lens 108 and the optical lens 208 are configured to condense a light beam in a desired cross section, or focus a light beam in the desired direction. In some embodiments, the optical lens 108 and the optical lens 208 are formed by a method of FIG. 12A to 12J described below, in which a local top view and a cross-sectional view taken along the I-I′ of the local top view are shown in each of FIG. 12A to 12J.

Referring to FIG. 12A, (N) mask pattern HM (wherein N=1) is formed on the substrate 101/201. In some embodiments, the mask pattern HM includes photoresist, silicon oxide, silicon nitride, silicon oxynitirde, silicon carbide, the like or a combination thereof, and the method of forming the mask pattern HM includes performing photolithography and etching processes.

Referring to FIG. 12B, the substrate 101/201 is partially removed by using the (N) mask pattern HM as an etching mask. The partial removing process EP may be a time-mode etching. In some embodiments, the partial removing process includes a wet etching process, a dry etching process or a combination thereof. The wet etching process includes NH₄OH, HNO₃, the like or a combination thereof. The dry etching process includes NF₃, F₂, Cl₂, the like or a combination thereof.

Thereafter, the (N) mask pattern HM is removed, so that the remaining substrate 101/201 has (N) protrusion. In some embodiments, the removing process includes a wet etching process, a dry etching process or a combination thereof. The wet etching process includes hot H₃PO₄ (about 150° C. to 170° C.) or the like.

Referring to FIG. 12C, (N+1) mask patterns HM (wherein N=1) are formed on the top of the (N) protrusion P and a region surrounding the (N) protrusion P of the remaining substrate 101/201. In some embodiments, the mask pattern HM includes photoresist, silicon oxide, silicon nitride, silicon oxynitirde, silicon carbide, the like or a combination thereof, and the method of forming the mask pattern HM includes performing photolithography and etching processes. Specifically, as shown in FIG. 12C, in the top view, the (N+1) mask patterns HM include a central circular pattern and an annular pattern surrounding the central circular pattern. In the cross-sectional view, the central circular pattern is located at a level higher than the level of the surrounding annular pattern.

Referring to FIG. 12D, the substrate 101/201 is partially removed by using the (N+1) mask patterns HM as an etching mask. The partial removing process EP may be a time-mode etching. In some embodiments, the partial removing process includes a wet etching process, a dry etching process or a combination thereof. The wet etching process includes NH₄OH, HNO₃, the like or a combination thereof. The dry etching process includes NF₃, F₂, Cl₂, the like or a combination thereof.

Thereafter, the (N+1) mask patterns HM are removed, so that the remaining substrate 101/201 has (N+1) protrusions having a stepped sidewall including (N) step(s). For example, as shown in FIG. 12D, the (N+1) protrusions incudes two protrusions having a stepped sidewall including one step (wherein N=1). Specifically, as shown in FIG. 12D, in the cross-sectional view, the central protrusion P is located at the highest level, the first annular protrusion P surrounding the central protrusion P is located at the next-highest level (i.e., the level lower than the highest level). In some embodiments, the removing process includes a wet etching process, a dry etching process or a combination thereof. Specifically, as shown in FIG. 12D, in the cross-sectional view, the central protrusion P is located at a level higher than the level of the annular protrusion P surrounding the central protrusion P.

In view of the foregoing, the steps of FIG. 12A to FIG. 12D are performed, wherein N=1.

Thereafter, the steps of FIG. 12C to FIG. 12D are repeated to perform steps of FIG. 12E to FIG. 12F, wherein N=2. For example, as shown in FIG. 12F, the (N+1) protrusions incudes three protrusions having a stepped sidewall including two steps (wherein N=2). Specifically, as shown in FIG. 12F, in the cross-sectional view, the central protrusion P is located at the higher level, the first annular protrusion P surrounding the central protrusion P is located at the middle level, and the second annular protrusion P surrounding the first annular protrusion P is located at the lower level.

Thereafter, the steps of FIG. 12C to FIG. 12D are repeated to perform steps of FIG. 12G to FIG. 12I, wherein N=3. For example, as shown in FIG. 12I, the (N+1) protrusions incudes four protrusions having a stepped sidewall including three steps (wherein N=3). Specifically, as shown in FIG. 12I, in the cross-sectional view, the central protrusion P is located at the highest level, the first annular protrusion P surrounding the central protrusion P is located at the next-highest level (i.e., the level lower than the highest level), and the second annular protrusion P surrounding the first annular protrusion P is located at the level lower than the next-highest level, and the third annular protrusion P surrounding the second annular protrusion P is located at the lowermost level.

In view of the foregoing, the steps of FIG. 12C to FIG. 12D can be repeated as many times as needed from N=2 to N=3 or from N=2 to N=4 or N=5, until the (N+1) protrusions form the nearly desired shape of the optical lens.

Referring to FIG. 12J, a rounding process RP is performed so that the (N+1) protrusions form the optical lens 108/208 having a dome-like shape. The rounding process may be referred to as a “smoothing process” in some examples. The rounding process RP may be a time-mode etching. In some embodiments, the rounding process RP includes a wet etching process. The wet etching process includes NH₄OH, HNO₃, the like or a combination thereof. As shown in FIG. 12J, in some embodiments, the optical lens 108/208 has a diameter D of about 100-200 μm. In some embodiments, the curvature radius of the optical lens 108/208 ranges from about 100 μm to 500 μm, or about 240 μm or more. In some embodiments, the optical lens 108/208 has a varied thickness ranging from about 1 μm to 50 μm, and the maximum thickness TH is greater than about 5 μm or 10 μm.

In the above embodiments, the optical lens 108 and the optical lens 208 are composed of silicon and are formed by directly etching the substrate 101 and the substrate 201 respectively with the method described in the FIG. 12A to FIG. 12J. However, the disclosure is not limited thereto. In other embodiments, the optical lens 108 and the optical lens 208 may be composed of silicon nitride. For example, a silicon nitride layer may be formed on the silicon substrate 101/201, and the method similar to that described in the FIG. 12A to FIG. 12J is performed to the silicon nitride layer, so as to form the silicon nitride optical lens 108/208.

Referring to FIG. 11 again, after the optical lens 108 is formed on the substrate 101 of the die 100 and the optical lens 208 is formed on the substrate 201 of the die 200, an anti-reflective coating (ARC) 109 is optionally formed over the optical lens 108, and an anti-reflective coating (ARC) 209 is optionally formed over the optical lens 208. The anti-reflective coatings (ARC) 109 and 209 are configured to improve the optical coupling performance. In some embodiments, each of the anti-reflective coating (ARC) 109 and the anti-reflective coating (ARC) 209 has a multi-layer structure including at least two silicon nitride layers and at least two silicon oxide layers alternatively stacked. Each of the silicon nitride layers and the silicon oxide layers of the anti-reflective coating (ARC) 109/209 ranges from about 0.1 μm to 5 μm (e.g., about 0.6 μm).

Thereafter, an encapsulation layer E is formed over the interposer structure 10 between the die 100 and the die 200. In some embodiments, the encapsulation layer E includes a molding compound, a molding underfill, a resin or the like. In some embodiments, the encapsulation layer E includes a polymer material such as polybenzoxazole (PBO), polyimide, benzocyclobutene (BCB), the like, or a combination thereof. The encapsulation layer E may be formed be a molding process followed by a curing process. A package assembly PK1 is thus completed.

Still referring to FIG. 11, an optical fiber 500 disposed over the die 100 or the die 200 corresponding to the optical lens 108 or the optical lens 208. In some embodiments, as shown in FIG. 11, the light path LP of a light beam emitted from the optical fiber 500 over the die 100 propagates through an optical lens 108, is optically coupled to the photonic integrated circuit 103, reflected by the mirror 21c of the glass substrate 20c and the mirror 21a of the glass substrate 20a, and then optically coupled to the photonic integrated circuit 13, reflected by the mirror 21b of the glass substrate 20b and the mirror 21d of the glass substrate 20d, and finally propagates through an optical lens 208. Similarly, the light path LP of a light beam can travel in a reverse direction opposite to the above direction when the light beam is emitted from the optical fiber 500 above the die 200. In some embodiments, the optical fiber 500 is arranged inclined with respect to the central axis of the optical lens 108 or 208. For example, the included angle β between the optical fiber 500 and the central axis of the optical lens 108 or 208 is about 5 degrees to 15 degrees for improving the coupling efficiency.

The above embodiments in which two anti-reflective coatings (ARC) are formed on opposite sides of the substrate for each die are provided for illustration purposes, and are not construed as limiting the present disclosure. In some embodiments, at least one of the two anti-reflective coatings (ARC) may be omitted from each die as needed.

FIG. 13 is a schematic local cross-sectional view of a package assemblies in accordance with some embodiments. The package assembly PK2 of FIG. 13 is similar to the package assembly PK1 of FIG. 11, so the difference between them is described below, and the similarity is not iterated herein.

In some embodiments, the anti-reflective coatings (ARC) 105 and 109 are omitted from the die 100 and the anti-reflective coatings (ARC) 205 and 209 are omitted from the die 200, so as to form the package assembly PK2.

The above embodiments in which the optical lens 108 and the optical lens 208 are formed protruding from the surfaces of the substrate 101 and the substrate 201 are provided for illustration purposes, and are not construed as limiting the present disclosure. In some embodiments, the optical lens is recessed from the surface of the substrate.

FIG. 14 is a schematic local cross-sectional view of a package assemblies in accordance with some embodiments. The package assembly PK3 of FIG. 14 is similar to the package assembly PK1 of FIG. 11, so the difference between them is described below, and the similarity is not iterated herein.

In the package assembly PK3, the optical lens 112 is recessed from the surface of the substrate 101 of the die 100, and the optical lens 212 is recessed from the surface of the substrate 201 of the die 200. In some embodiments, each of the optical lens 112 and the optical lens 212 has a substantially vertical sidewall and a convex bottom. In some embodiments, the method of forming the optical lens 112 and the optical lens 212 includes performing an etching process or a laser process to formed an optical recessed features 110 and 210. In some embodiments, an optical material or transparent material is optionally filled in the optical recessed feature 110 to form the optical lens 112, and an optical material or transparent material is optionally filled in the optical recessed feature 210 to form the optical lens 212. The optical material having a transmission percentage of about 80-99% (e.g., 85-95% or 88-92%). In some embodiments, the optical material includes an optical liquid silicone rubber, poly (methyl methacrylate) (PMMA), an optical epoxy, the like, or a combination thereof. In some embodiments, the optical material includes a high numerical aperture (NA) material having a NA of about 0.2 to 0.5. In some embodiments, the optical material is formed using dispensing, injecting, and/or spraying process, followed by a planarization process.

Another difference between the package assembly PK3 and the package assembly PK1 lies in that, in the package assembly PK3, the anti-reflective coatings (ARC) 109 and 209 may be omitted as needed.

FIG. 15 illustrates a method of forming a package assembly in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S400, an interposer structure including a first tilted metal layer and a second tilted metal layer facing each other is provided. In some embodiments, a method of forming the interposer structure includes: forming a lower insulating layer on the substrate; forming a first glass substrate having the first tilted metal layer on the lower insulating layer; forming a second glass substrate having the second tilted metal layer on the lower insulating layer; and forming an upper insulating layer over the first glass substrate and the second glass substrate covering the first tilted metal layer and the second tilted metal layer. In some embodiments, after forming the first glass substrate and the second glass substrate and before forming the upper insulating layer, at least one optical component is formed between the first tilted metal layer and the second tilted metal layer. FIG. 4 to FIG. 8 illustrate cross-sectional views corresponding to some embodiments of act S400.

At act S402, a first die and a second die are provided, wherein the first die includes a first substrate and a third tilted metal layer embedded in a first insulating layer on the first substrate, and the second die includes a second substrate and a fourth tilted metal layer embedded in a second insulating layer on the second substrate. FIG. 9 illustrates a cross-sectional view corresponding to some embodiments of act S402.

At act S404, the first die and the second die are bonded to the interposer structure with the first substrate and the second substrate facing up, so that a light beam from an optical fiber over the first die is reflected by the third tilted metal layer, the first tilted metal layer, the second tilted metal layer, and the fourth tilted metal layer sequentially. In some embodiments, the first die and the second die are bonded to the interposer structure through a hybrid bonding comprising a dielectric-to-dielectric bonding and a metal-to-metal bonding. FIG. 10 illustrates a cross-sectional view corresponding to some embodiments of act S404.

In some embodiments, a first optical lens is further formed on the first substrate of the first die, and a second optical lens is further formed on the second substrate of the second die. See FIG. 11 and FIG. 13, for example.

In some embodiments, a third die and a fourth die are provided. In some embodiment, the third die includes a first electronic integrated circuit, wherein the third die is located aside the first die and electrically connected to the interposer structure. The fourth die includes a second electronic integrated circuit, wherein the fourth die is located aside the second die and electrically connected to the interposer structure. See FIG. 1, for example.

In some embodiments, a method of forming the first optical lens on the first substrate of the first die includes: (a) forming (N) mask pattern(s) on the first substrate; (b) partially removing the first substrate by using the (N) mask pattern(s) as an etching mask; (c) removing the (N) mask pattern(s), so that the remaining first substrate has (N) protrusion(s); (d) forming (N+1) mask patterns on top(s) of the (N) protrusion(s) and a region surrounding the (N) protrusion(s) of the remaining first substrate; (e) partially removing the first substrate by using the (N+1) mask patterns as an etching mask; and (f) removing the (N+1) mask patterns, so that the remaining first substrate has (N+1) protrusions, wherein N is a positive integer. In some embodiments, in steps (a) to (f), N=1. In some embodiments, the method of forming the first optical lens on the first substrate of the first die further includes: (g) repeating step (a) to step (f), wherein N=2. In some embodiments, a rounding process is performed, so that the (N+1) protrusions form the first optical lens having a dome-like shape. See FIG. 12A to FIG. 12J, for example.

FIG. 16 illustrates a method of forming a package assembly in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S500, a first glass substrate and a second glass substrate are provided, wherein the first glass substrate has a first titled sidewall coated with a first mirror, and the second glass substrate has a second tilted sidewall coated with a second mirror. In some embodiments, a method of providing the first glass substrate having the first mirror and the second glass substrate having the second mirror includes: providing a plurality of blanket glass substrates; beveling the plurality of blanket glass substrates, so that each beveled glass substrate has a tilted sidewall; standing the beveled glass substrates on a temporary holder with tilted sidewalls facing up; depositing a metal material on the tilted sidewalls; and removing the temporary holder from the beveled glass substrates. FIG. 2A to FIG. 3B illustrate different views corresponding to some embodiments of act S500.

At act S502, the first glass substrate and the second glass substrate are bonded to a silicon substrate with the first mirror and the second mirror facing up. FIG. 4 to FIG. 6 illustrate cross-sectional views corresponding to some embodiments of act S502.

At act S504, a blanket bonding structure is formed over the first glass substrate and the second glass substrate. FIG. 7 to FIG. 8 illustrate cross-sectional views corresponding to some embodiments of act S504.

At act S506, a first die and a second die are provided, wherein the first die includes a first insulating layer having a first photonic integrated circuit therein and a first bonding structure on the first insulating layer, and the second die includes a second insulating layer having a second photonic integrated circuit therein and a second bonding structure on the second insulating layer. FIG. 9 illustrates a cross-sectional view corresponding to some embodiments of act S506.

At act S508, the first bonding structure of the first die is bonded to the blanket bonding structure and the second bonding structure of the second die is bonded to the blanket bonding structure. In some embodiments, the first die further comprises a third mirror embedded in the first insulating layer and corresponding to the first mirror, and the second die further comprises a fourth mirror embedded in the second insulating layer and corresponding to the second mirror. In some embodiments, a method of forming the third mirror includes: proving a third glass substrate having a third titled sidewall coated with the third mirror; and embedding the third glass substrate with the first insulating layer. FIG. 10 and FIG. 11 illustrate cross-sectionals view corresponding to some embodiments of act S508.

In some embodiments, a third die and a forth die are provided. The third die includes a first electronic integrated circuit, wherein the third die is located aside the first die and electrically connected to the interposer structure. The fourth die includes a second electronic integrated circuit, wherein the fourth die is located aside the second die and electrically connected to the interposer structure. See FIG. 1, for example.

In some embodiments, a first optical lens is formed on the first die and a second optical lens is formed on the second die. See FIG. 11, FIG. 12A to FIG. 12J and FIG. 13, for example.

The structures of the package assemblies are illustrated below with reference to FIG. 11, FIG. 13 and FIG. 14.

In some embodiments of the disclosure, a package assembly PK1/PK2/PK3 includes an interposer structure 10, a first die 100 and a second die 200. The interposer structure 10 has a first tilted metal layer 21a and a second tilted metal layer 21b embedded therein and facing each other. The first die 100 is located on the interposer structure 10, wherein the first die 100 includes a first optical integrated circuit 103 and a third tilted metal layer 21c embedded in a first insulating layer 102/104, and the third tilted metal layer 21c of the first die 100 corresponds to the first tilted metal layer 21a of the interposer structure 10. The second die 200 is located on the interposer structure 10, wherein the second die 200 includes a second optical integrated circuit 203 and a fourth tilted metal layer 21d embedded in a second insulating layer 202/204, and the fourth tilted metal layer 21d of the second die 200 corresponds to the second tilted metal layer 21b of the interposer structure 10.

In some embodiments, the package assembly PK1/PK2 further includes a first optical lens 108 located on a first substrate 101 of the first die 100, and a second optical lens 208 located on a second substrate 201 of the second die 200. The first optical lens 108 and the second optical lens 208 are convex optical lenses. In other embodiments, the package assembly PK3 further includes a first optical lens 112 located in a first substrate 101 of the first die 100, and a second optical lens 212 located in a second substrate 201 of the second die 200. The first optical lens 112 and the second optical lens 212 are recessed optical lenses.

In some embodiments, the package assembly PK1/PK2/PK3 further includes a third die 300 and a fourth die 400 (as shown in FIG. 1). The third die 300 is located aside the first die 100 and electrically connected to the interposer structure 10, wherein the third die 300 includes a first electronic integrated circuit. The fourth die 400 is located aside the second die 200 and electrically connected to the interposer structure 10, wherein the fourth die 400 includes a second electronic integrated circuit.

In some embodiments, the package assembly PK1/PK2/PK3 further includes at least one optical component 13 disposed between the first tilted metal layer 21a and the second tilted metal layer 21b. In some embodiments, the at least one optical component 13 includes a first edge coupler ECa, a second edge coupler ECb and a waveguide structure WS between the first edge coupler ECa and the second coupler ECb, the first edge coupler ECa is laterally aligned with the first tilted metal layer 21a, and the second edge coupler ECb is laterally aligned with the second tilted metal layer 21b.

The above embodiments in which two photonic dies are provided on the interposer structure are provided for illustration purposes, and are not construed as limiting the present disclosure. In other embodiments, at least one die is provided on the interposer structure between the two photonic dies, and the at least one die may be a photonic die or an electronic die.

FIG. 17 is a simplified top view of a package assembly in accordance with some embodiments. For clarity and illustration purposes, only dies and interposer structure are shown in FIG. 17. In some embodiments, FIG. 18 is a schematic cross-sectional view of a package assembly taken along the line A-A of FIG. 17.

The package assembly PK4 of FIG. 18 is similar to the package assembly PK1 of FIG. 11, so the difference between them is described below, and the similarity is not iterated herein. In the package assembly PK4, the interposer structure 10 is provided with four glass substrates 20a, 20b′, 20a′ and 20b, counting from left to right in FIG. 18. In some embodiments, the glass substrate 20a has a titled sidewall TS1 coated with a mirror 21a, the glass substrate 20b′ having a tilted sidewall TS2′ coated with a mirror 21b′, the glass substrate 20a′ has a titled sidewall TS1′ coated with a mirror 21a′, and the glass substrate 20b having a tilted sidewall TS2 coated with a mirror 21b. The glass substrates 20a and 20a′ with mirrors 21a and 21a′ may have the same element configuration and may be fabricated by the same process. The glass substrates 20b and 20b′ with mirrors 21b and 21b′ may have the same element configuration and may be fabricated by the same process. In some embodiments, the glass substrates 20a and 20b′ are placed on the interposer structure 10 with the mirrors 21a and 21b′ facing each other, and the glass substrates 20a′ and 20b are placed on the interposer structure 10 with the mirrors 21a′ and 21b facing each other. In this embodiments, the glass substrates 20b′ and 20a′ are placed on the interposer structure 10 with the mirrors 21b′ and 21a′ facing away from each other, and are located between the glass substrate 20a and the glass substrate 20b. In some embodiments, a photonic integrated circuit (PIC) 13 is formed between the mirror 21a and the mirror 21b′, and another photonic integrated circuit (PIC) 13 is formed between the mirror 21a′ and the mirror 21b. In some embodiments, there is no PIC between the mirror 21b′ and the mirror 21a′, and the glass substrate 20b′ is in contact with the glass substrate 20a′.

As shown in FIG. 18, a die 600 is provided over and bonded to the interposer structure 10. In some embodiments, the die 600 includes a substrate 601, an insulating layer 602, a glass substrate 20d′, a photonic integrated circuit 603, a glass substrate 20c′, an insulating layer 604, and bonding metal features 606. The die 600 is bonded to the interposer structure 10 through the bonding structures BS6 and BS0. Such bonding process is referred to as a “hybrid bonding process” including a metal-to-metal bonding and a dielectric-to-dielectric bonding, in which the bonding metal features 606 are bonded to the bonding metal features 16, and the insulating layer of the bonding structure BS6 is bonded to the insulating layer of the bonding structure BS0.

In some embodiments, the substrate 601, the insulating layer 602, the photonic integrated circuit 603, the insulating layer 604 and the bonding metal features 606 are similar to the substrate 101, the insulating layer 102, the photonic integrated circuit 103, the insulating layer 604 and bonding metal features 106, and the glass substrate 20d′ and the glass substrate 20c′ are similar to the glass substrate 20d and the glass substrate 20c, so the materials, configurations and forming methods of these elements may refer to those of similar elements described in the above embodiments. In some embodiments, the glass substrate 20d′ and the glass substrate 20c′ are placed laterally with the mirrors 21d′ and 21c′ facing each other, and the photonic integrated circuit 603 is disposed between the glass substrate 20d′ and a glass substrate 20c′.

In some embodiments, an anti-reflective coating (ARC) 605 is optionally formed between the substrate 601 and the insulating layer 602, and an anti-reflective coating (ARC) 209 is optionally formed over the substrate 601 opposite to the anti-reflective coating (ARC) 605. The anti-reflective coatings (ARC) 605 and 609 are similar to the anti-reflective coatings (ARC) 105 and 109, so the materials, configurations and forming methods of these elements may refer to those of similar elements described in the above embodiments. In some embodiments, no optical lens is formed on the die 600.

In some embodiments, as shown in FIG. 18, the die 600 is bonded to the interposer structure 10 with the substrate 601 facing up, so that the light beam LP from the optical fiber 500 over the die 100 is reflected by the tilted metal layer 21c, the tilted metal layer 21a, the tilted metal layer 21b′, the tilted metal layer 21d′, the tilted metal layer 21c′, the tilted metal layer 21a′, the tilted metal layer 21b, and the tilted metal layer 21d sequentially.

In the embodiments of FIG. 18, the die 600 is a photonic die, but the disclosure is not limited thereto. In other embodiments, the die 600 may be an electronic die, a dummy die or a bridge die. In some embodiments, the electronic die 600 includes an electronic integrated circuit (EIC). For examples, the electronic die 600 includes electronic components such as an active component, a passive component or a combination thereof. In some embodiments, the dummy die 600 includes a silicon die. In some embodiments, the bridge die 600 serves as an interposer for providing electrical connection between the electronic dies 300 and 400.

FIG. 19 is a simplified top view of a package assembly in accordance with some embodiments. For clarity and illustration purposes, only dies and interposer structure are shown in FIG. 17. In some embodiments, FIG. 19 is a schematic cross-sectional view of a package assembly taken along the line A-A of FIG. 17.

The package assembly PK5 of FIG. 19 is similar to the package assembly PK4 of FIG. 18, so the difference between them is described below, and the similarity is not iterated herein. In some embodiments, the glass substrates 20b′ and 20a′ and one PIC 13 are omitted from the interposer structure 10, and all optical components (e.g., the glass substrates 20d′ and 20c′, the PIC 603, etc.) are omitted from the die 600, so as to form the package assembly PK5.

In some embodiments, as shown in FIG. 19, the die 600 is bonded to the interposer structure 10, so that the light beam LP from the optical fiber 500 over the die 100 is reflected by the tilted metal layer 21c, the tilted metal layer 21a, the tilted metal layer 21b, and the tilted metal layer 21d sequentially.

In each of the package assembly PK4 of FIG. 18 and the package assembly PK5 of FIG. 19, anti-reflective coatings (ARC) 605 and 609 may be omitted, so as to form a package assembly similar to the package assembly PK2 with adding one more die 600 between the dies 100 and 200.

In each of the package assembly PK4 of FIG. 18 and the package assembly PK5 of FIG. 19, an optical lens is recessed from the surface of the substrate 101 of the die 100, and an optical lens is recessed from the surface of the substrate 201 of the die 200, so as to form a package assembly similar to the package assembly PK3 with adding one more die 600 between the dies 100 and 200.

In view of above, mirrors are fabricated on thinned glass substrates in a mass production, so as to significantly reduce the cycle time of a package assembly. The appropriate number of the glass substrates with the mirrors is then embedded in suitable positions of an interposer structure and at least two photonic dies, so that the interposer structure is optically coupled to the at least two photonic dies, and therefore the coupling efficiency is greatly improved. With optical interconnection provided by the interposer structure and the photonic dies, higher communication performance and more compact packaging can be easily achieved.

Many variations of the above examples are contemplated by the disclosure. It is understood that different embodiments may have different advantages, and that no particular advantage is necessarily required of all embodiments.

In accordance with some embodiments of the disclosure, a method of forming a package assembly includes following operations. An interposer structure, a first die and a second die are provided. The interposer structure includes a first tilted metal layer and a second tilted metal layer facing each other. The first die includes a first substrate and a third tilted metal layer embedded in a first insulating layer on the first substrate. The second die includes a second substrate and a fourth tilted metal layer embedded in a second insulating layer on the second substrate. The first die and the second die are bonded to the interposer structure with the first substrate and the second substrate facing up, so that a light beam from an optical fiber over the first die is reflected by the third tilted metal layer, the first tilted metal layer, the second tilted metal layer, and the fourth tilted metal layer sequentially.

In accordance with some embodiments of the disclosure, a method of forming a package assembly includes following operations. A first glass substrate and a second glass substrate are provided, wherein the first glass substrate has a first titled sidewall coated with a first mirror, and the second glass substrate has a second tilted sidewall coated with a second mirror are provided. The first glass substrate and the second glass substrate are bonded to a silicon substrate with the first mirror and the second mirror facing up. A blanket bonding structure is formed over the first glass substrate and the second glass substrate. A first die and a second die are provided, wherein the first die includes a first insulating layer having a first photonic integrated circuit therein and a first bonding structure on the first insulating layer, and the second die includes a second insulating layer having a second photonic integrated circuit therein and a second bonding structure on the second insulating layer. The first bonding structure of the first die is bonded to the blanket bonding structure and the second bonding structure of the second die is bonded to the blanket bonding structure.

In accordance with some embodiments of the disclosure, a package assembly includes an interposer structure, a first die and a second die. The interposer structure has a first tilted metal layer and a second tilted metal layer embedded therein and facing each other. The first die is located on the interposer structure, wherein the first die includes a first optical integrated circuit and a third tilted metal layer embedded in a first insulating layer, and the third tilted metal layer of the first die corresponds to the first tilted metal layer of the interposer structure. The second die is located on the interposer structure, wherein the second die includes a second optical integrated circuit and a fourth tilted metal layer embedded in a second insulating layer, and the fourth tilted metal layer of the second die corresponds to the second tilted metal layer of the interposer structure.

The package assembly of the disclosure has high coupling efficiency, small beam size, easy integration with the existing process, less I/O pin counts, high speed and high data rate optical transmission, etc. Besides, the package assembly of the disclosure exhibits good die-to-die transmission in any 3DIC structure, and provides wider process window for the fiber shift issue.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A method of forming a package assembly, comprising:
providing an interposer structure comprising a first tilted metal layer and a second tilted metal layer facing each other;
providing a first die comprising a first substrate and a third tilted metal layer embedded in a first insulating layer on the first substrate, and providing a second die comprising a second substrate and a fourth tilted metal layer embedded in a second insulating layer on the second substrate; and
bonding the first die and the second die to the interposer structure with the first substrate and the second substrate facing up, so that a light beam from an optical fiber over the first die is reflected by the third tilted metal layer, the first tilted metal layer, the second tilted metal layer, and the fourth tilted metal layer sequentially.

2. The method of claim 1, wherein a method of forming the interposer structure comprises:
forming a lower insulating layer on the substrate;
forming a first glass substrate having the first tilted metal layer on the lower insulating layer;
forming a second glass substrate having the second tilted metal layer on the lower insulating layer; and
forming an upper insulating layer over the first glass substrate and the second glass substrate covering the first tilted metal layer and the second tilted metal layer.

3. The method of claim 2, further comprising, after forming the first glass substrate and the second glass substrate and before forming the upper insulating layer, forming at least one optical component between the first tilted metal layer and the second tilted metal layer.

4. The method of claim 1, wherein the first die and the second die are bonded to the interposer structure through a hybrid bonding comprising a dielectric-to-dielectric bonding and a metal-to-metal bonding.

5. The method of claim 1, wherein the interposer structure further comprises a fifth tilted metal layer and a sixth tilted metal layer facing away from each other and between the first tilted metal layer and the second tilted metal layer, and wherein the method further comprises:
providing a third die comprising a third substrate and a seventh tilted metal layer and an eighth tilted metal layer embedded in a third insulating layer on the third substrate; and
bonding the third die with the third substrate facing up, so that the light beam from the optical fiber over the first die is reflected by the third tilted metal layer, the first tilted metal layer, the fifth tilted metal layer, the seventh tilted metal layer, the eighth tilted metal layer, the sixth tilted metal layer, the second tilted metal layer, and the fourth tilted metal layer sequentially.

6. The method of claim 1, further comprises forming a first optical lens on the first substrate of the first die and forming a second optical lens on the second substrate of the second die.

7. The method of claim 6, wherein a method of forming the first optical lens on the first substrate of the first die comprises:
(a) forming (N) mask pattern(s) on the first substrate;
(b) partially removing the first substrate by using the (N) mask pattern(s) as an etching mask;
(c) removing the (N) mask pattern(s), so that the remaining first substrate has (N) protrusion(s);
(d) forming (N+1) mask patterns on top(s) of the (N) protrusion(s) and a region surrounding the (N) protrusion(s) of the remaining first substrate;
(e) partially removing the first substrate by using the (N+1) mask patterns as an etching mask; and
(f) removing the (N+1) mask patterns, so that the remaining first substrate has (N+1) protrusions having a stepped sidewall including (N) step(s), wherein N is a positive integer.

8. The method of claim 7, wherein in steps (a) to (f), N=1, and the method further comprises:
(g) repeating step (a) to step (f), wherein N=2.

9. The method of claim 8, further comprising performing a rounding process so that the (N+1) protrusions form the first optical lens having a dome-like shape.

10. A method of forming a package assembly, comprising:
providing a first glass substrate having a first titled sidewall coated with a first mirror and providing a second glass substrate having a second tilted sidewall coated with a second mirror;
bonding the first glass substrate and the second glass substrate to a silicon substrate with the first mirror and the second mirror facing up;
forming a blanket bonding structure over the first glass substrate and the second glass substrate;
providing a first die comprising a first photonic integrated circuit and a first bonding structure, and providing a second die having a second photonic integrated circuit and a second bonding structure; and
bonding the first bonding structure of the first die to the blanket bonding structure and bonding the second bonding structure of the second die to the blanket bonding structure.

11. The method of claim 10, wherein the first die further comprises a third mirror embedded in a first insulating layer and corresponding to the first mirror, and the second die further comprises a fourth mirror embedded in a second insulating layer and corresponding to the second mirror.

12. The method of claim 11, wherein a method of forming the third mirror comprises:
proving a third glass substrate having a third titled sidewall coated with the third mirror; and
embedding the third glass substrate with the first insulating layer.

13. The method of claim 10, wherein a method of providing the first glass substrate having the first mirror and the second glass substrate having the second mirror comprises:
providing a plurality of blanket glass substrates;
beveling the plurality of blanket glass substrates, so that each beveled glass substrate has a tilted sidewall;
standing the beveled glass substrates on a temporary holder with tilted sidewalls facing up;
depositing a metal material on the tilted sidewalls; and
removing the temporary holder from the beveled glass substrates.

14. The method of claim 10, wherein an included angle between the first tilted sidewall and an adjacent surface of the first glass substrate ranges from about 30 degrees to 80 degrees, and the first mirror has a thickness ranging from about 1 μm to 100 μm, and wherein an included angle between the second tilted sidewall and an adjacent surface of the second glass substrate ranges from about 30 degrees to 80 degrees, and the second mirror has a thickness ranging from about 1 μm to 100 μm.

15. The method of claim 10, further comprising:
forming a first optical lens on the first die and forming a second optical lens on the second die.

16. A package assembly, comprising:
an interposer structure, having a first tilted metal layer and a second tilted metal layer embedded therein and facing each other;
a first die, located on the interposer structure, wherein the first die comprises a first optical integrated circuit and a third tilted metal layer, and the third tilted metal layer of the first die corresponds to the first tilted metal layer of the interposer structure; and
a second die, located on the interposer structure, wherein the second die comprises a second optical integrated circuit and a fourth tilted metal layer, and the fourth tilted metal layer of the second die corresponds to the second tilted metal layer of the interposer structure.

17. The package assembly of claim 16, further comprising:
a first optical lens, located on the first die; and
a second optical lens, located on the second die.

18. The package assembly of claim 16, further comprising:
a third die located aside the first die and electrically connected to the interposer structure, wherein the third die comprises a first electronic integrated circuit; and
a fourth die located aside the second die and electrically connected to the interposer structure, wherein the fourth die comprises a second electronic integrated circuit.

19. The package assembly of claim 16, further comprising at least one optical component disposed between the first tilted metal layer and the second tilted metal layer.

20. The package assembly of claim 19, wherein the at least one optical component comprises a first edge coupler, a second edge coupler and a waveguide structure between the first edge coupler and the second coupler, the first edge coupler is laterally aligned with the first tilted metal layer, and the second edge coupler is laterally aligned with the second tilted metal layer.
